(19) United States
(12) Patent Application Publication
(10) Pub. No.: US 2022/0098221 A1
(43) Pub. Date: Mar. 31, 2022

(54) LIGHT-EMITTING MATERIAL INCLUDING LIGHT-EMITTING COMPOUND, LIGHT EMITTING DEVICE INCLUDING LIGHT-EMITTING MATERIAL, METHOD OF PREPARING LIGHT-EMITTING MATERIAL, AND METHOD OF PREPARING LIGHT-EMITTING COMPOUND

(71) Applicant: Samsung Electronics Co., Ltd., Suwon-si (KR)

(72) Inventor: YongChul KIM, Seoul (KR)

(21) Appl. No.: 17/477,674

(22) Filed: Sep. 17, 2021

(30) Foreign Application Priority Data
Sep. 28, 2020 (KR) 10-2020-0126373

(51) Int. Cl. C07F 7/08; C09K 11/66; C01G 21/00; H01L 51/00

(52) U.S. Cl. CPC C07F 7/0836; C09K 11/665; C01G 21/006; C01P 2004/61; C01P 2006/60; H01L 2251/301; C01P 2004/03; H01L 51/0094

(57) ABSTRACT

A light-emitting material including aminosiloxane and a light-emitting compound represented by Formula 1, a light-emitting device including the light-emitting material, a method of preparing the light-emitting material, and a method of preparing the light-emitting compound represented by Formula 1:

A¹B¹X¹₃, Formula 1
wherein A¹ may be an alkali metal, B¹ may be Pb, Sn, or any combination thereof, and X¹ may be a halogen.

### CROSS-REFERENCE TO RELATED APPLICATION

This application claims priority under 35 U.S.C. § 119 to Korean Patent Application No. 10-2020-0126373, filed on Sep. 28, 2020, in the Korean Intellectual Property Office, the disclosure of which is herein incorporated by reference in is entirety.

### BACKGROUND

### Field

A light-emitting material including a light-emitting compound, a light-emitting device including the light-emitting material, a method of preparing the light-emitting material, and a method of preparing the light-emitting compound.

### Description of Related Art

Light-emitting devices are devices that convert electrical energy into light energy.

Typical light-emitting devices include an anode, a cathode, and an emission layer positioned between the anode and the cathode. Additionally, a hole transport region may be between the anode and the emission layer, and an electron transport region may be between the emission layer and the cathode. Holes provided from the anode move toward the emission layer through the hole transport region, and electrons provided from the cathode move toward the emission layer through the electron transport region. The holes and the electrons recombine in the emission layer to produce excitons. The electronic transition of an exciton in an excited state to the ground state results in the emission of light.

### SUMMARY

One or more embodiments include a light-emitting material including a light-emitting compound, a light-emitting device including the light-emitting material, a method of preparing the light-emitting material, and a method of preparing the light-emitting compound. In particular, one or more embodiments include a light-emitting material in which the luminescence efficiency of the material following heat treatment may not significantly decrease, a light-emitting device including the light-emitting material, a method of preparing the light-emitting material, and a method of preparing the light-emitting compound.

Additional aspects will be set forth in part in the description which follows and, in part, will be apparent from the description, or may be learned by a person of skill in the practice of the embodiments of the disclosure.

According to an aspect of an embodiment, a light-emitting material may include an aminosiloxane and a light-emitting compound represented by Formula 1:

A¹B¹X¹₃ Formula 1

wherein, in Formula 1,

A¹ may be an alkali metal,

B¹ may be Pb, Sn, or any combination thereof, and

X¹ may be a halogen.

According to one or more embodiments, A¹ may be Cs, B¹ may be Pb, and X¹ may be Cl, Br, I, or any combination thereof.

According to one or more embodiments, the light-emitting compound represented by Formula 1 may include CsPbBr₃, CsPbBrₓCl₍₃₋ₓ₎, wherein x may be a real number greater than 0 and less than 3, CsPbCl₃, or any combination thereof.

According to one or more embodiments, the aminosiloxane may include a structural unit represented by Formula 2:

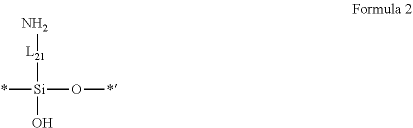

wherein, in Formula 2,

L₂₁ may be a substituted or unsubstituted C₁-C₁₀ alkylene group, and

* and *′ each indicate a binding site to an adjacent atom.

According to one or more embodiments, the light-emitting material may further include a dopant represented by Formula 3:

C¹X¹ Formula 3

wherein, in Formula 3,

C¹ may be H, methylammonium (MA), formamidinium (FA), an alkali metal, or any combination thereof, and

X¹ may be halogen.

According to one or more embodiments, the light-emitting material may further include an amino alkoxysilane.

According to one or more embodiments, a light-emitting device may include: a first electrode and aa second electrode each having a surface opposite the other; and an emission layer positioned between the first electrode and the second electrode, wherein the emission layer may include the light-emitting material.

According to one or more embodiments, the light-emitting device may include a hole transport region between the first electrode and the emission layer, an electron transport region between the emission layer and the second electrode, or a hole transport region between the first electrode and the emission layer and an electron transport region between the emission layer and the second electrode.

According to one or more embodiments, the light-emitting device may include a charge control layer between the first electrode and the emission layer, a charge control between the emission layer and the second electrode, or a charge control layer between the first electrode and the emission layer and a charge control layer between the emission layer and the second electrode.

According to one or more embodiments, a method of preparing a light-emitting material may include: providing a mixture of a light-emitting compound, amino alkoxysilane, and a solvent on a substrate; and heat-treating the substrate.

According to one or more embodiments, the heat-treating may be performed at a temperature of 100° C. or higher.

According to one or more embodiments, a method of preparing a light-emitting compound may include: mixing a first precursor solution, which includes a first precursor and a first solvent, with a second precursor solution, which includes a second precursor and a second solvent, to form a precipitate; separating the precipitate and dispersing the separated precipitate in a third solvent; and adding a first compound to the dispersed precipitate to obtain the light-emitting compound, wherein a solubility of the first precursor in the first solvent may be greater than a solubility of the first precursor in the second solvent, a solubility of the second precursor in the second solvent may be greater than a solubility of the second precursor in the first solvent, and the third solvent may be different from the first compound.

According to one or more embodiments, the third solvent may include a sulfoxide group.

According to one or more embodiments, the third solvent may be dimethyl sulfoxide (DMSO) or methyl phenyl sulfoxide (MPSO).

According to one or more embodiments, the first compound may be ethyl acetate (EA), DMSO, tetramethylene sulfoxide (TMSO), or diphenyl sulfoxide (DPSO).

According to one or more embodiments, the third solvent may be DMSO, and the first compound may be ethyl acetate, the third solvent may be methyl phenyl sulfoxide, and the first compound may be dimethyl sulfoxide, the third solvent may be methyl phenyl sulfoxide, and the first compound may be tetramethylene sulfoxide, or the third solvent may be dimethyl sulfoxide, and the first compound may be diphenyl sulfoxide.

According to one or more embodiments, the light-emitting compound may include a compound represented by Formulae 3, 4, or 5:

A³B³X³₃ Formula 3

A⁴B⁴₂X⁴₅ Formula 4

A⁵₄B⁵X⁵₆ Formula 5

wherein, in Formulae 3, 4, or 5,

A³, A⁴, and A⁵ may each independently be an alkali metal,

B³, B⁴, and B⁵ may each independently be Pb, Sn, or any combination thereof, and

X³, X⁴, and X⁵ may each independently be a halogen.

According to one or more embodiments;

i) the light-emitting compound may include the light-emitting compound represented by Formula 3, and may not include the light-emitting compound represented by Formula 4 and the light-emitting compound represented by Formula 5,

ii) the light-emitting compound may include the light-emitting compound represented by Formula 3 and the light-emitting compound represented by Formula 4, and may not include the light-emitting compound represented by Formula 5,

iii) the light-emitting compound may include the light-emitting compound represented by Formula 3 and the light-emitting compound represented by Formula 5, and may not include the light-emitting compound represented by Formula 4, or

iv) the light-emitting compound may include the light-emitting compound represented by Formula 5, and may not include the light-emitting compound represented by Formula 3 and the light-emitting compound represented by Formula 4.

According to one or more embodiment, the light-emitting compound may include the light-emitting compound represented by Formula 3 and may not include the light-emitting compound represented by Formula 4 and the light-emitting compound represented by Formula 5.

According to one or more embodiments, the first solvent may include water, and the second solvent may include hexamethyl phosphoamide (HMPA).

### BRIEF DESCRIPTION OF THE DRAWINGS

The features, and advantages of certain embodiments of the disclosure will be more apparent from the following description taken in conjunction with the accompanying drawings, in which:

FIG. 1 is a schematic cross-sectional view of a light-emitting device according to an embodiment;

FIG. 2A is a scanning electron microscope (SEM) image of Light-emitting Compound 1-1;

FIG. 2B is an SEM image of light-emitting Compound 1-2;

FIG. 2C is an SEM image of light-emitting Compound 1-3;

FIG. 2D is an SEM image of Light-emitting Compound 1-4; and

FIG. 3 is a graph of wavelength (nanometers, nm) versus intensity (arbitrary unit, a.u.) from the photoluminescence spectra of Samples 1, 2, and 3 and Comparative Samples 1, 2, and 3.

### DETAILED DESCRIPTION

Reference will now be made in detail to embodiments, examples of which are illustrated in the accompanying drawings, wherein like reference numerals refer to like elements throughout. As the inventive concept allows for various changes and numerous embodiments, particular embodiments will be illustrated in the drawings and described in detail in the written description. Effects, features, and a method of achieving the inventive concept will be obvious by referring to example embodiments of the inventive concept with reference to the attached drawings. The same reference numerals in the drawings refer to the same components, and the size of each component in the drawings may be exaggerated or reduced for clarity and convenience of description. The inventive concept may, however, be embodied in many different forms and should not be construed as being limited to the embodiments set forth herein.

Most of the terms used herein are general terms that have been widely used in the technical art to which the inventive concept pertains. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein. However, some of the terms used herein may reflect intentions of technicians in this art, precedents, or new technologies. Also, some of the terms used herein may be arbitrarily chosen by applicant. In this case, these terms are defined in detail below. Accordingly, the specific terms used herein should be understood based on the unique meanings thereof and the whole context of the inventive concept.

When a part such as a layer, film, area, plate, or the like is described to be “on” another part, this description is construed as including not only the case where the part is “directly on” the other part but also the case where another part is interposed therebetween. On the other hand, when an element is described to be “directly on” another element, this description is construed as having no other element interposed between the two elements.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer, or section. Thus, “a first element,” “component,” “region,” “layer,” or “section” discussed below could be termed a second element, component, region, layer, or section without departing from the teachings herein.

As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within 10% of the stated value.

In the present specification, the term “Group” refers to a group on the IUPAC Periodic Table of Elements.

In the present specification, the term “alkali metal” refers to a Group 1 element, or a combination of two or more different Group 1 elements.

In the present specification, the term “halogen” refers to a Group 17 element or a combination of two or more different Group 17 elements.

In the present specification, the term “maximum emission wavelength” refers to a wavelength value at a maximum emission intensity in a photoluminescence (PL) spectrum that is obtained for a sample solution or sample film sample including a compound.

In the present specification, “full width at half maximum (FWHM)” refers to a wavelength width corresponding to one half of the maximum emission intensity in the aforementioned PL spectrum.

Hereinafter, a light-emitting compound, a method of manufacturing the light-emitting material, and a light-emitting device including the light-emitting compound will be described in detail with reference to the accompanied drawings.

### Light-Emitting Material

According to one or more embodiments, a light-emitting material may include aminosiloxane and a light-emitting compound represented by Formula 1:

A¹B¹X¹₃ Formula 1

wherein, in Formula 1,

A¹ may be an alkali metal,

B¹ may be Pb, Sn, or any combination thereof, and

X¹ may be a halogen.

As the light-emitting material includes aminosiloxane, boundary defects of the light-emitting compound represented by Formula 1 may be compensated or minimized. While not wishing to be bound by theory, an amino group of the aminosiloxane may compensate or minimize boundary defects of the light-emitting compound. Accordingly, the light-emitting material may exhibit enhanced stability following a high temperature heat treatment, thus maintaining a high photoluminescent (PL) intensity following the heat treatment.

In some embodiments, in Formula 1, A¹ may be Cs, B¹ may be Pb, and X¹ may be Cl, Br, I, or any combination thereof.

In some embodiments, the light-emitting compound represented by Formula 1 may include CsPbBr₃, CsPbBrₓCl₍₃₋ₓ₎, wherein x may be a real number greater than 0 and less than 3, CsPbCl₃, or any combination thereof.

In some embodiments the light-emitting compound represented by Formula 1 may be categorized as being a platelet type or a cubic type.

In some embodiments, the aminosiloxane may derive from the use of an amino alkoxysilane in the preparation of the light emitting compound. For example, in some embodiments, the aminosiloxane may derive from a hydrolysis reaction of an amino alkoxysilane used in the preparation of the light emitting compound.

In some embodiments, the aminosiloxane may include a unit structure represented by Formula 2:

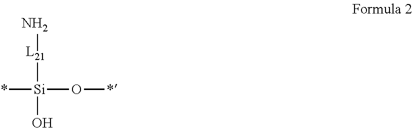

wherein, in Formula 2,

L₂₁ may be a substituted or unsubstituted C₁-C₁₀ alkylene group, and

* and *′ each indicate a binding site to an adjacent atom.

In some embodiments, in Formula 2, L₂₁ may be a substituted or unsubstituted methylene group, a substituted or unsubstituted ethylene group, or a substituted or unsubstituted propylene group.

In some embodiments, in Formula 2, L₂₁ may be a substituted or unsubstituted propylene group.

In some embodiments, the light-emitting material may further include a dopant represented by Formula 3:

C¹X¹ Formula 3

wherein, in Formula 3,

C¹ may be H, methylammonium (MA), formamidinium (FA), an alkali metal, or any combination thereof, and

X¹ may be halogen.

For example, the dopant represented by Formula 3 may include HBr, methylammonium bromide (MABr), or any combination thereof.

In some embodiments, the light-emitting material may further include amino alkoxysilane.

For example, the amino alkoxysilane may be represented by H₂N-L₂₁-Si(ORₐ)(OR_{b})(OR_{c}), wherein L₂₁ may be a substituted or unsubstituted C₁-C₁₀ alkylene group, and Rₐ, R_{b}, and R_{c} may each independently be a substituted or unsubstituted C₁-C₁₀ alkyl group.

In some embodiments, the amino alkoxysilane may be represented by H₂N-L₂₁-Si(ORₐ)(OR_{b})(OR_{c}), L₂₁ may be a substituted or unsubstituted methylene group, a substituted or unsubstituted ethylene group, or a substituted or unsubstituted propylene group, and Rₐ, R_{b}, and R_{c} may each independently be a methyl group, an ethyl group, or a propyl group.

In some embodiments, the amino alkoxysilane may be 3-aminopropyltriethoxy silane.

The light-emitting material may emit green light.

A maximum emission wavelength (experimental value) of the light-emitting material may be in a range of about 500 nanometers (nm) or longer and about 550 nm or shorter, or for example, in a range of about 500 nm or longer and about 530 nm or shorter.

A full width at half maximum (FWHM) of the light-emitting material may be 70 nm or shorter. In some embodiments, a FWHM of the light-emitting material may be 30 nm or shorter, or for example, 20 nm or shorter.

According to one or more embodiments, maximum emission wavelength (experimental value) of the light-emitting material may be in a range of about 500 nm or longer and about 530 nm or shorter, and have a FWHM may be 30 nm or shorter, or for example, 20 nm or shorter. The light-emitting material may have a relatively high stability even at a high temperature.

### Method of Preparing Light-Emitting Material

According to one or more embodiments, a method of preparing a light-emitting material may include: applying a mixture of a light-emitting compound represented by Formula 1, amino alkoxysilane, and a solvent onto a substrate; and heat-treating the substrate:

A¹B¹X¹₃ Formula 1

wherein, in Formula 1,

A¹ may be an alkali metal,

B¹ may be Pb, Sn, or any combination thereof, and

X¹ may be a halogen.

The amino alkoxysilane may by hydrolyzed by reaction with water present in the air to form the aminosiloxane. Since water present in the air may react with the amino alkoxysilane before the light-emitting compound represented by Formula 1, decomposition of the light-emitting compound may be suppressed or minimized. Accordingly, even after the light-emitting material is exposed to a high temperature heat treatment, PL intensity may be essentially maintained. For example, the PL intensity may only decrease following a heat treatment by no more than 30%, no more than 20%, or no more than 10%, then the PL intensity prior to the heat treatment.

The light-emitting compound may be understood by referring to the description of the light-emitting compound described above.

The amino alkoxysilane may be understood by referring to the description of the amino alkoxysilane described above.

In some embodiments, the solvent may include a third solvent and/or a first compound. The third solvent may be understood by referring to the description of the amino alkoxysilane described herein.

In some embodiments, the heat-treating may be performed at a temperature of 100° C. or higher. In some embodiments, the heat-treating may be performed at a temperature in a range of about 120° C. to about 180° C.

In some embodiments, the heat-treating may be performed in air. The amino alkoxysilane may be hydrolyzed by reaction with water present in the air, thus being converted into aminosiloxane.

### Method of Preparing Light-Emitting Compound

The light-emitting compound represented by Formula 1 may be obtained according to the method of preparing the light-emitting compound described herein.

A method of preparing a light-emitting compound may include: mixing a first precursor solution, which includes a first precursor and a first solvent, with a second precursor solution, which includes a second precursor and a second solvent, to form a precipitate; separating the precipitate and dispersing the separated precipitate in a third solvent; and adding a first compound to the dispersed precipitate to obtain a light-emitting compound, wherein a solubility of the first precursor in the first solvent may be greater than a solubility of the first precursor in the second solvent, a solubility of the second precursor in the second solvent may be greater than a solubility of the second precursor in the first solvent, and the third solvent may be different from the first compound.

In some embodiments, the first solvent may be different from the second solvent. In some embodiments, as the first solvent may be different from the second solvent, a solubility of the first precursor in the first and second solvents and a solubility of the second precursor in the first and second solvents may be different from each other.

In some embodiments, the first precursor may be soluble in the first solvent. In some embodiments, 1 gram (g) or more of the first precursor may be dissolved at a temperature of 25° C. under 1 atmosphere, based on 100 g of the first solvent. In some embodiments, a concentration of the first precursor solution may be 1 molar (M) or greater at a temperature of 25° C. under 1 atmosphere, or in a range of about 1 M to about 10 M at a temperature of 25° C. under 1 atmosphere.

In some embodiments, the second precursor may be soluble in the second solvent. In some embodiments, 1 g or more of the second precursor may be dissolved at a temperature of 25° C. under 1 atmosphere, based on 100 g of the second solvent. In some embodiments, a concentration of the second precursor solution may be 1 M or greater at a temperature of 25° C. under 1 atmosphere, 1 M or greater at a temperature of 80° C. under 1 atmosphere, or in a range of about 1 M to about 2 M at a temperature of 80° C. under 1 atmosphere.

In some embodiments, the first solvent may include water. In some embodiments, the first solvent may consist of water.

In some embodiments, the second solvent may include hexamethyl phosphamide (HMPA). In some embodiments, the second solvent may consist of HMPA.

According to one or more embodiments, the first precursor solution and the second precursor solution may each not include an acid. In general, an inorganic acid such as HBr or an organic acid such as an oleic acid may be used to increase a solubility of a light-emitting compound precursor. However, in the method of preparing the light-emitting compound, even in the absence of an acid, the first precursor may be dissolved in the first solvent in a relatively high concentration, and the second precursor may be dissolved in the second solvent in a relatively high concentration.

According to one or more embodiments, the first precursor solution and the second precursor solution may each not include a base. In the method of preparing the light-emitting compound, even in the absence of a base, the first precursor may be dissolved in the first solvent in a relatively high concentration, and the second precursor may be dissolved in the second solvent in a relatively high concentration.

The forming of a precipitate may be performed by adding the second precursor solution dropwise to the first precursor solution with or without stirring. In some embodiments, a precipitate is formed by adding dropwise the second precursor solution to the first precursor solution as the first precursor solution is stirred.

The forming of a precipitate may be performed at a temperature lower than a boiling point of the first precursor solution. In some embodiments, the forming of a precipitate may be performed in a temperature range of about 20° C. to about 90° C. or about 50° C. to about 80° C.

The third solvent may be different from the first compound, and a solubility of the precipitate in the third solvent may be different from a solubility of the precipitate in the first compound. Accordingly, when the first compound is added to the third solvent, the precipitate dissolved in the third solvent may undergo recrystallization to provide a recrystallized form of the light-emitting compound.

In some embodiments, the third solvent may include a sulfoxide group. While not wishing to be bound by theory, as the third solvent includes a sulfoxide group, boundary defects of the precipitate may be compensated or minimized.

In some embodiments, the third solvent may be a solvent that may dissolve or partially dissolve the precipitate.

In some embodiments, the third solvent may be dimethyl sulfoxide (DMSO) or methyl phenyl sulfoxide (MPSO).

In some embodiments, in order to substantially and completely dissolve the precipitate in the third solvent, the precipitate may be separated and dispersed in the third solvent, and then, the third solvent may be heated at a temperature lower than a boiling point.

In some embodiments, the first compound may be ethyl acetate (EA), DMSO, tetramethylene sulfoxide (TMSO), or diphenyl sulfoxide (DPSO).

In some embodiments, i) the third solvent may be DMSO, and the first compound may be ethyl acetate, ii) the third solvent may be methyl phenyl sulfoxide, and the first compound may be dimethyl sulfoxide, iii) the third solvent may be methyl phenyl sulfoxide, and the first compound may be tetramethylene sulfoxide, or iv) the third solvent may be dimethyl sulfoxide, and the first compound may be diphenyl sulfoxide.

In some embodiments, the first precursor may include a compound represented by Formula P1:

A¹X¹ Formula P1

wherein, in Formula P1, A¹ may be an alkali metal, and X¹ may be a halogen.

In some embodiments, the second precursor may include a compound represented by Formula P2:

B²X²₂ Formula P2

wherein, in Formula P2, B² may be Pb or Sn, and X² may be a halogen.

For example, in Formulae P1 and P2, A¹ may be Cs, B² may be Pb, and X¹ and X² may each independently be Cl, Br, or I.

In some embodiments, in Formulae P1 and P2, a case where X¹ and X² may each be I may be excluded. When X¹ and X² are each 1, stability of the prepared light-emitting compound may be low, and/or the preparative yield of the light-emitting compound may be unsatisfactory.

In some embodiments, the first precursor may include CsCl, CsBr, or any combination thereof.

In some embodiments, the second precursor may include PbCl₂, PbBr₂, or any combination thereof.

According to one or more embodiments, i) the first precursor may further include CsI, ii) the second precursor may further include PbI₂, or iii) the first precursor may further include CsI, and the second precursor may further include PbI₂.

According to one or more embodiments, a mole ratio of the first precursor to the second precursor may be in a range of about 0.5:1 to about 5.0:1. When the mole ratio is satisfied, the light-emitting compound may have a desired composition.

In some embodiments, the light-emitting compound may be poorly soluble or insoluble in the second solvent and the third solvent, and thus, the light-emitting compound may be obtained with an increased yield. In some embodiments, 0.1 g or less of the light-emitting compound may be dissolved at a temperature of 25° C. under 1 atmosphere, based on 100 g of the first solvent, and 0.1 g or less of the light-emitting compound may be dissolved at a temperature of 25° C. under 1 atmosphere, based on 100 g of the second solvent, and 0.1 g or less of the light-emitting compound may be dissolved at a temperature of 25° C. under 1 atmosphere, based on 100 g of the third solvent.

In some embodiments, the light-emitting compound may include a compound represented by Formulae 3, 4, or 5:

A³B³X³₃ Formula 3

A⁴B⁴₂X⁴₅ Formula 4

A⁵₄B⁵X⁵₆ Formula 5

wherein, in Formulae 3, 4, or 5,

A³, A⁴, and A⁵ may each independently be an alkali metal,

B³, B⁴, and B⁵ may each independently be Pb, Sn, or any combination thereof, and

X³, X⁴, and X⁵ may each independently be a halogen.

In some embodiments: i) the light-emitting compound may include the light-emitting compound represented by Formula 3, and may not include the light-emitting compound represented by Formula 4 and the light-emitting compound represented by Formula 5; ii) the light-emitting compound may include the light-emitting compound represented by Formula 3 and the light-emitting compound represented by Formula 4, and may not include the light-emitting compound represented by Formula 5; iii) the light-emitting compound may include the light-emitting compound represented by Formula 3 and the light-emitting compound represented by Formula 5, and may not include the light-emitting compound represented by Formula 4: or iv) the light-emitting compound may include the light-emitting compound represented by Formula 5, and may not include the light-emitting compound represented by Formula 3 and the light-emitting compound represented by Formula 4.

In some embodiments, the light-emitting compound may include the light-emitting compound represented by Formula 3, and may not include the light-emitting compound represented by Formula 4 and the light-emitting compound represented by Formula 5.

In some embodiments, a mole ratio of the first precursor to the second precursor may be in a range of about 1:1 to about 1.5:1, and the light-emitting compound may include the light-emitting compound represented by Formula 3 and the light-emitting compound represented by Formula 4, and may not include the light-emitting compound represented by Formula 5.

In some embodiments, a mole ratio of the first precursor to the second precursor may be in a range of about 1.5:1 to about 4.0:1, and the light-emitting compound may include the light-emitting compound represented by Formula 3 and the light-emitting compound represented by Formula 5, and may not include the light-emitting compound represented by Formula 4.

In some embodiments, a mole ratio of the first precursor to the second precursor may be in a range of about 4.0:1 to about 5.0:1, and the light-emitting compound may include the light-emitting compound represented by Formula 5, and may not include the light-emitting compound represented by Formula 3 and the light-emitting compound represented by Formula 4.

In some embodiments, the method may further include washing the separated precipitate before drying. In some embodiments, the method may further include washing the separated precipitate with ethanol and/or diethyl ether. Accordingly, any remaining first precursor and/or the second precursor in the precipitate may be removed by the washing. Accordingly, the light-emitting compound would have an increase in purity.

In some embodiments, the drying may be performed in a temperature range of about 40° C. to about 80° C. In some embodiments, the drying may be performed in a temperature of 60° C.

In some embodiments, the drying may be performed in a vacuum atmosphere.

In some embodiments, the drying may be performed for 10 hours or longer, or for example, 12 hours or longer.

According to one or more embodiments, the method of preparing the light-emitting compound may further include: applying a mixture including the light-emitting material and a fourth solvent onto a substrate; applying a fifth solvent on the substrate for crystallization; and heat-treating the substrate, e.g., to remove the fourth solvent and the fifth solvent. Accordingly, the substrate on which the light-emitting material is formed may have a more cubic crystalline form.

In some embodiments, the mixture may be applied by spin-coating onto a substrate. When the mixture is applied by spin-coating, the spin-coating conditions may be selected from, e.g., a coating rate of about 300 revolutions per minute (rpm) to about 4,000 rpm and a temperature range of about 80° C. to about 200° C., depending on the composition of the mixture. In some embodiments, the coating rate may be controlled depending on the section. For example, the coating rate may be maintained in a range of about 300 rpm to about 700 rpm in a first section, and in a range of about 2,000 rpm to about 4,000 rpm in the second section.

The mixture may be applied onto a substrate by various known methods in the art of coating substrates with a mixture.

In some embodiments, when the mixture is applied by spin-coating, the mixture may be first spin-coated onto the substrate, and the antisolvent may be added dropwise to the applied mixture or by spraying onto the applied mixture, while rotating the substrate.

In some embodiments, the fourth solvent may be dimethyl formamide, dimethyl sulfoxide, γ-butyrolactone, N-methyl-2-pyrrolidone, or any combination thereof, and

the fifth solvent may be diethyl ether, toluene, α-terpineol, hexyl carbitol, ethyl acetate, butyl carbitol acetate, hexyl cellosolve, butyl cellosolve acetate, or any combination thereof.

In some embodiments, the fourth solvent may be dimethyl sulfoxide, and the fifth solvent may be diethyl ether, toluene, ethyl acetate, or any combination thereof. Subsequently, the fourth solvent and the fifth solvent may be removed from the substrate-applied mixtures by heat-treating.

In some embodiments, the heat-treating condition may include a time range from 12 about 15 minutes to about 2 hours, and a temperature range from about 50° C. to about 100° C., depending on the composition of the mixture.

According to one or more embodiments, the method of preparing the light-emitting material may further include heat-treating a mixture including the light-emitting material and the fourth solvent. The fourth solvent and the heat-treating may respectively be understood by referring to the descriptions of the third solvent and the heat-treating provided herein.

### Light-Emitting Device

According to an embodiment, a light-emitting device 1 may include: a first electrode 110 and a second electrode 190, each electrode having a face opposite the other; and an emission layer 150 positioned between the first electrode 110 and the second electrode 190, wherein the emission layer 150 may include the light-emitting material.

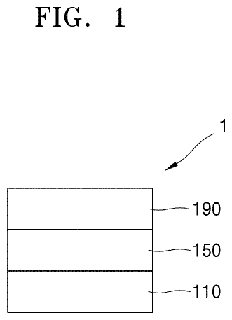

The structure of the light-emitting device 1 will be described in detail with reference to FIG. 1. FIG. 1 is a schematic cross-sectional view of the light-emitting device 1 according to an embodiment. Although it is not shown in FIG. 1, a substrate may be further disposed under the first electrode 110 (opposite the emission layer 150) and/or on the second electrode 190 (opposite the emission layer 150). The substrate may be a conventional substrate used in light-emitting devices, e.g., a glass substrate or a transparent plastic substrate, each having excellent mechanical strength, thermal stability, transparency, surface smoothness, ease of handling, and water repellency.

The first electrode 110 may be an anode to which (+) voltage is applied, and the second electrode 190 may be a cathode to which (−) voltage is applied. In contrast, the first electrode 110 may be a cathode, and the second electrode 190 may be an anode. For convenience of description, the case where the first electrode 110 is an anode, and the second electrode 190 is a cathode will be described.

The first electrode 110 may be formed by depositing or sputtering, onto the substrate, a material for forming the first electrode 110. The first electrode 110 may be a reflective electrode, a semi-transmissive electrode, or a transmissive electrode. In some embodiments, to provide for a bottom emission light-emitting device, the first electrode 110 may be a semi-transmissive electrode or a transmissive electrode. In some embodiments, to provide for a top emission light-emitting device, the first electrode 110 may be a reflective electrode, and such a variation may be made. The first electrode 110 may have a single-layered structure or a multi-layered structure including a plurality of layers.

The first electrode 110 may include a material with a high work function for easy hole injection. In some embodiments, the material for forming the first electrode 110 may 12 be indium tin oxide (ITO), indium zinc oxide (IZO), indium oxide, tin oxide (SnO₂), zinc oxide (ZnO), gallium oxide, or a combination thereof. In some embodiments, the material for forming the first electrode 110 may be a metal, such as magnesium (Mg), aluminum (Al), aluminum-lithium (Al—Li), calcium (Ca), magnesium-indium (Mg—In), magnesium-silver (Mg—Ag), or a combination thereof.

The second electrode 190 may be disposed to face the first electrode 110. The second electrode 190 may be a reflective electrode, a semi-transmissive electrode, or a transmissive electrode. In some embodiments, to provide for a bottom emission light-emitting device, the second electrode 190 may be a reflective electrode. In some embodiments, to provide for a top emission light-emitting device, the second electrode 190 may be a semi-transmissive electrode or a transmissive electrode, and such a variation may be made. The second electrode 190 may have a single-layered structure or a multi-layered structure including a plurality of layers.

The second electrode 190 may include a metal, alloy, an electrically conductive compound, or a combination thereof with a relatively low work function. In some embodiments, a material for forming the second electrode 190 may be lithium (Li), magnesium (Mg), aluminum (Al), aluminum-lithium (Al—Li), calcium (Ca), gallium (Ga), magnesium-indium (Mg—In), magnesium-silver (Mg—Ag), or a combination thereof. In some embodiments, the material for forming the second electrode 190 may include ITO, IZO, or a combination thereof.

The emission layer 150 may include the aforementioned light-emitting material. In the emission layer 150, electrons and holes generated by a voltage applied to the first electrode 110 and the second electrode 190 may be combined. The combination of the electrons and holes in the light-emitting material generate excitons, and upon relaxation of the exciton from an excited state to a ground state light is emitted from the material. The light-emitting device may have high color purity, high current efficiency, and high quantum yield by including the light-emitting compound represented by Formula 1 as described above.

The light-emitting material may be understood by referring to the description of the light-emitting material provided herein.

The light-emitting material may be distributed across a thickness direction of an emission layer of a device in a homogeneous or uniform concentration, or the light-emitting material may be distributed at a constant or variable concentration gradient across a thickness direction of the emission layer.

When the light-emitting device is a full-color light-emitting device, individual sub-pixels may include emission layers emitting different colors.

In some embodiments, the emission layer may be patterned into a first color emission layer, a second color emission layer, and a third color emission layer, according to a sub-pixel. In this embodiment, at least one emission layer among the foregoing emission layers may necessarily include the light-emitting material. In some embodiments, the first color emission layer may be an emission layer including the light-emitting compound, and the second color emission layer and the third color emission layer may be organic emission layers each including different organic compounds. In this embodiment, the first color to the third color may be different from one another, and in some embodiments, the first color to the third color may each have different maximum emission wavelengths. The first color to the third color may be combined to be white light.

In some embodiments, the emission layer may further include a fourth color emission layer, at least one emission layer of the first color to the fourth color emission layers may be an emission layer including the light-emitting material, and the other emission layers may be organic emission layers each including different organic compounds. Such a variation may be made. In this embodiment, the first color to the fourth color may be different from one another, and in some embodiments, the first color to the fourth color may each have different maximum emission wavelengths.

The first color to the fourth color may be combined to be white light.

In some embodiments, the light-emitting device may have a structure in which at least two emission layers each emitting different wavelengths of light may be in contact with or spaced apart from each other. At least one emission layer of the at least two emission layers may be an emission layer including the light-emitting compound, and the other emission layer may be organic emission layer including organic compounds. Such a variation may be made.

The emission layer 150 may further include, in addition to the light-emitting material, at least one of an organic compound, another inorganic compound, an organic-inorganic composite compound, or quantum dots, but embodiments are not limited thereto.

The thickness of the emission layer 150 may be in a range of about 10 nm to about 200 nm, for example, about 50 nm to about 100 nm. When the thickness of the emission layer 150 is within any of these ranges, improved luminescence characteristics may be obtained without a substantial increase in driving voltage.

An additional layer may be further included between the first electrode 110 and the emission layer 150 and/or between the second electrode 190 and the emission layer 150 to improve device characteristics such as luminescence efficiency by adjusting the charge carrier balance inside the device. In some embodiments, a hole transport region may be further included between the first electrode 110 and the emission layer 150, and an electron transport region may be further included between the second electrode 190 and the emission layer 150.

The hole transport region may serve to inject and/or transport holes from the first electrode 110 to the emission layer 150. In addition, the hole transport region may also compensate for an optical resonance distance depending on a wavelength of light emitted from the emission layer to improve the efficiency of an organic light-emitting device.

The hole transport region may include at least one of a hole injection layer, a hole transport layer, or a charge control layer. The hole transport region may be a single layer or a multi-layered structure including two or more layers. In some embodiments, the hole transport region may include a hole injection layer only or a hole transport layer only. In some embodiments, the hole transport region may include a hole injection layer and a hole transport layer which are sequentially stacked on the first electrode 110. In some embodiments, the hole transport region may include a hole injection layer, a hole transport layer, and a hole control layer, which are sequentially stacked on the first electrode 110.

In some embodiments, the hole transport region may include, for example, 1,3-bis(9-carbazolyl)benzene (mCP), 4,4′-bis(N-carbazolyl)-1,1′-biphenyl (CBP), 3,3-bis(carbazol-9-yl)biphenyl (mCBP), 4,4′,4″-tris[phenyl(m-tolyl)amino]triphenylamine (m-MTDATA), TDATA, 2-TNATA, N,N′-di(1-naphthyl)-N,N′-diphenyl-(1,1′-biphenyl)-4,4′-diamine (NPB), β-NPB, N,N′-bis(3-methylphenyl)-N,N′-diphenybenzidine (TPD), spiro-TPD, spiro-NPB, methylated-NPB, TAPC, HMTPD, tris(4-carbazoyl-9-ylphenyl)amine (TCTA), polyaniline/dodecybenzenesulfonic acid (PANI/DBSA), poly(3,4-ethylenedioxythiophene)/poly(4-styrene sulfonate) (PEDOT/PSS), poly(9,9-dioctyl-fluorene-co-N-(4-butylphenyl)-diphenylamine) (TFB), polyarylamine, poly(N-vinylcarbazole) (PVK), polypyrrole, polyaniline/camphor sulfonic acid (PANI/CSA), or polyaniline/poly(4-styrenesulfonate) (PANI/PSS), but embodiments are not limited thereto:

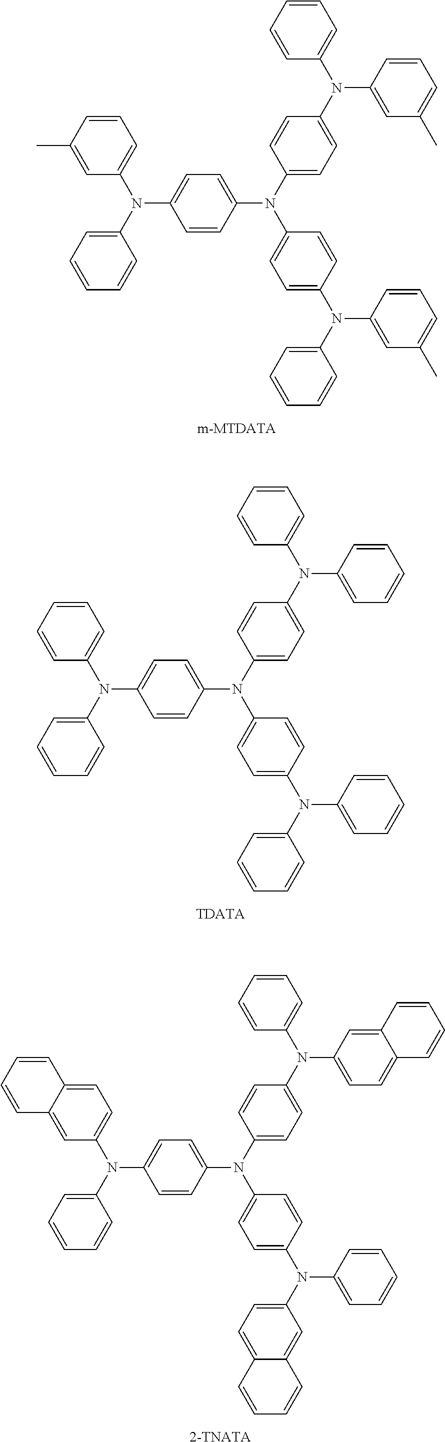

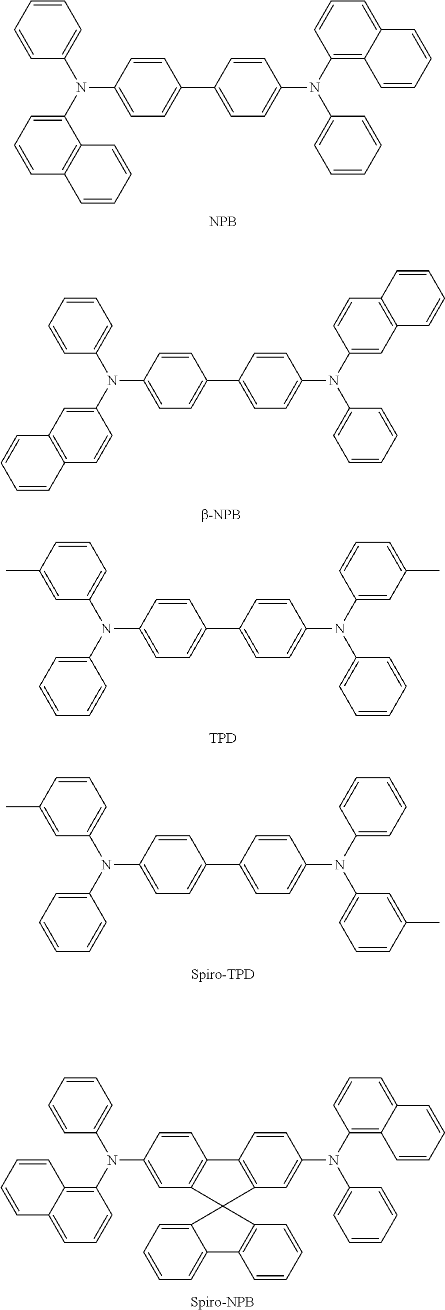

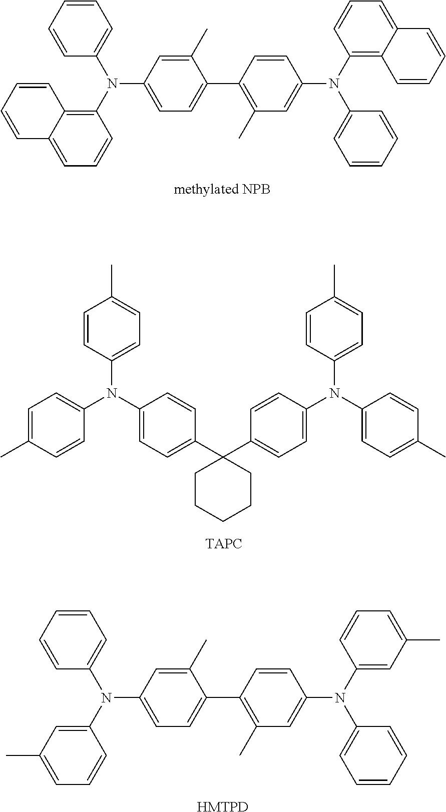

The thickness of the hole transport region may be determined in consideration of the wavelength of light emitted from the emission layer, the driving voltage of the light-emitting device, current efficiency, or the like. In some embodiments, the thickness of the hole transport region may be in a range of about 10 nm to about 1,000 nm, and in some embodiments, in a range of about 10 nm to about 100 nm. When the hole transport region includes the hole injection layer and the hole transport layer, the thickness of the hole injection layer may be in a range of about 10 nm to about 200 nm, and the thickness of the hole transport layer may be in a range of about 5 nm to about 100 nm.

The hole transport region may include a p-dopant as well as the aforementioned materials to improve conductive properties of the hole transport region. The p-dopant may be substantially homogeneously or non-homogeneously dispersed in the hole transport region.

The p-dopant may include one of a quinone derivative, a metal oxide, and a compound containing a cyano group, but embodiments are not limited thereto. For example, non-limiting examples of the p-dopant include a quinone derivative, such as tetracyanoquinodimethane (TCNQ) or 2,3,5,6-tetrafluoro-tetracyano-1,4-benzoquinonedimethane (F4-TCNQ); a metal oxide, such as a tungsten oxide or a molybdenum oxide; and a compound containing a cyano group, such as Compound HAT-CN (dipyrazino[2,3-f:2′,3′-h]quinoxaline-2,3,6,7,10,11-hexacarbonitrile), but embodiments are not limited thereto:

The electron transport region may serve to inject and/or transport electrons from the second electrode 190 to the emission layer 150. In addition, the electron transport region may also compensate for an optical resonance distance depending on a wavelength of light emitted from the emission layer to improve the efficiency of an organic light-emitting device.

The electron transport region may include at least one of an electron injection layer, an electron transport layer, or a charge control layer. The electron transport region may be a single layer or a multi-layered structure including two or more layers. In some embodiments, the electron transport region may include an electron injection layer only or an electron transport layer only. In some embodiments, the hole transport region may include a structure of electron transport layer/electron injection layer or charge control layer/electron transport layer/electron injection layer, which are sequentially stacked on the emission layer 150.

The electron transport region may include, for example, at least one of Alq3, bathocuproine (BCP), 4,7-diphenyl-1,10-phenanthroline (Bphen), bis(2-methyl-8-quinolinolato-N1,08)-(1,1′-biphenyl-4-olato)aluminum (Balq), 3-(biphenyl-4-yl)-5-(4-tert-butylphenyl)-4-phenyl-4H-1,2,4-triazole (TAZ), 4-(naphthalen-1-yl)-3,5-diphenyl-4H-1,2,4-triazole (NTAZ), bis(10-hydroxybenzo[h]quinolinato)beryllium (Bebg2), B3PYMPM, TPBI, 3TPYMB, BmPyPB, TmPyPB, BSFM, PO-T2T, and PO15, but embodiments are not limited thereto. In some embodiments, the electron transport layer and/or the charge control layer may include at least one of the foregoing compounds, but embodiments are not limited thereto.

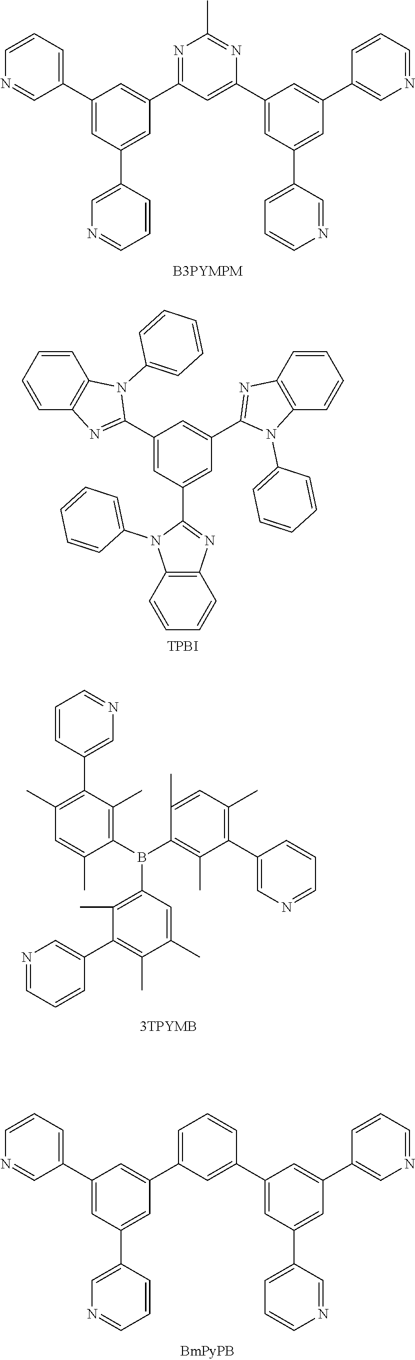

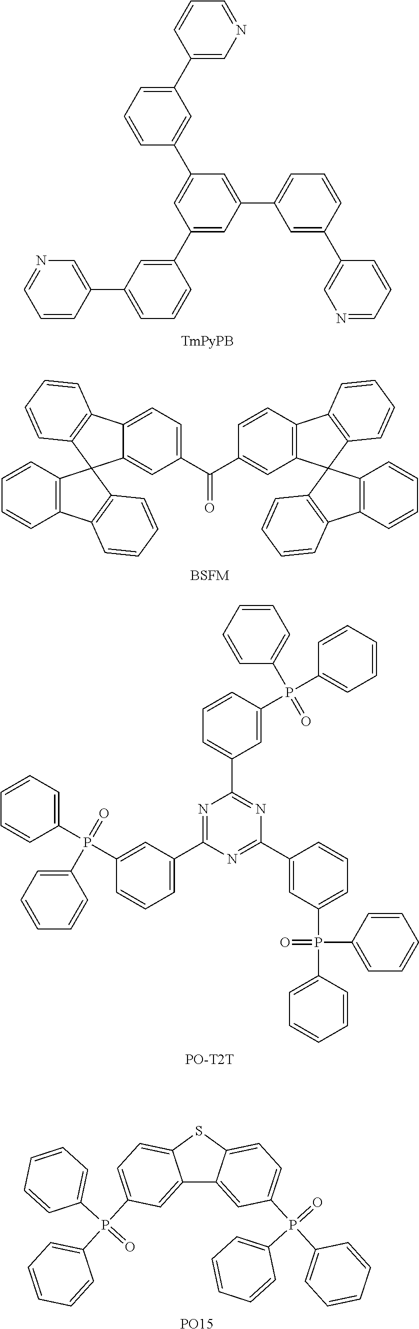 [SMILES: c1cncc(-c2cccc(-c3cc(-c4cccc(-c5cccnc5)c4)cc(-c4cccc(-c5cccnc5)c4)c3)c2)c1 ; O=C(c1ccc2c(c1)C1(c3ccccc3-c3ccccc31)c1ccccc1-2)c1ccc2c(c1)C1(c3ccccc3-c3ccccc31)c1ccccc1-2 ; O=P(c1ccccc1)(c1ccccc1)c1cccc(-c2nc(-c3cccc(P(=O)(c4ccccc4)c4ccccc4)c3)nc(-c3cccc(P(=O)(c4ccccc4)c4ccccc4)c3)n2)c1 ; "PO-T2T" ; "PO15" ; O=P(c1ccccc1)(c1ccccc1)c1ccc2sc3ccc(P(=O)(c4ccccc4)c4ccccc4)cc3c2c1]

In some embodiments, the electron injection layer may consist of an alkali metal, an alkaline earth metal, a rare earth metal, an alkali metal compound, an alkaline earth metal compound, a rare earth metal compound, an alkali metal complex, an alkaline earth metal complex, a rare earth metal complex, or a combination thereof. In some embodiments, the electron injection layer may further include organic materials described above, but embodiments are not limited thereto.

In some embodiments, the electron injection layer may further include LiF, NaF, CsF, KF, Li₂O, Cs₂O, K₂O, BaO, SrO, CaO, 8-quinolinolato lithium (LiQ), or any combination thereof. In some embodiments, the electron injection layer may further include the foregoing organic compounds, but embodiments are not limited thereto.

The thickness of the electron transport region may be determined in consideration of the wavelength of light emitted from the emission layer, the driving voltage of the light-emitting device, current efficiency, or the like. In some embodiments, the thickness of the electron transport region may be in a range of about 1 nm to about 1,000 nm, and in some embodiments, in a range of about 1 nm to about 200 nm. When the electron transport region includes the electron injection layer and the electron transport layer, the thickness of the electron injection layer may be in a range of about 1 nm to about 50 nm, and the thickness of the electron transport layer may be in a range of about 5 nm to about 100 nm.

The charge control layer may be included to adjust the charge injection balance at an interface between the layer including an organic compound (e.g., a hole transport layer, an electron transport layer, or the like) and the layer including an inorganic compound (e.g., an emission layer). The charge control layer may include a polymeric compound, e.g., poly(methyl methacrylate) (PMMA), polyimide (PI), poly vinyl alcohol (PVA), or any combination or copolymer thereof, but embodiments are not limited thereto. By including the electron control layer, since the charge injection balance of the light-emitting device may be improved, thereby increasing the external quantum yield. In addition, as the electron control layer is directly adjacent to the emission layer, the emission layer may be flat, and the driving voltage of the light-emitting device may be lowered.

According to an embodiment, the light-emitting device may include a hole transport region between the first electrode and the emission layer and/or an electron transport region between the emission layer and the second electrode.

In some embodiments, the light-emitting device may include a charge control layer between the first electrode and the emission layer and/or between the emission layer and the second electrode.

Each layer in the light-emitting device 1 may be formed by various methods, such as vacuum deposition, spin coating, casting, Langmuir-Blodgett (LB) deposition, or the like.

When a hole injection layer is formed by vacuum-deposition, for example, the vacuum deposition may be performed at a temperature in a range of about 100° C. to about 500° C., at a vacuum degree in a range of about 10⁻⁸ torr to about 10⁻³ torr, and at a rate in a range of about 0.01 Angstroms per second (Å/sec) to about 100 Å/sec, though the conditions may vary depending on a compound used as a hole injection material and a structure and thermal properties of a desired hole injection layer, but embodiments are not limited thereto.

When a hole injection layer is formed by spin coating, the spin coating may be performed at a rate in a range of about 2,000 revolutions per minute (rpm) to about 5,000 rpm and at a temperature in a range of about 80° C. to 200° C. to facilitate removal of a solvent after the spin coating, though the conditions may vary depending on a compound used as a hole injection material and a structure and thermal properties of a desired hole injection layer, but embodiments are not limited thereto.

Hereinbefore, the light-emitting device has been described with reference to FIG. 1, but is not limited thereto.

Hereinafter, the light-emitting material according to an embodiment, a method of preparing the light-emitting material, and a light-emitting device including the light-emitting material will be described in more detail with reference to Synthesis Examples and Examples; however, embodiments are not limited thereto. The term “B was used instead of A” used in describing Synthesis Examples means that an identical mole equivalent of B was used in place of A.

### EXAMPLES

### Analysis Method

Measurement of Photoluminescence (PL) Spectrum

(1) A light-emitting compound was coated on a glass substrate to form a film having a thickness of in a range of 5 nanometers (nm) to 20 nm. A PL spectrum of the film was measured using an ISC PC1 spectrofluorometer at room temperature by excitation under nitrogen atmosphere with excitation light having a wavelength of 365 nm, 400 nm, or 450 nm.

(2) Measurement of photoluminescent quantum yield (PLQY)

A light-emitting compound was coated on a glass substrate to form a film having a thickness of in a range of 5 nm to 20 nm. A PLQY of the film was measured using C9920-2-12 and PMA-11 (Hamamatsu Photonics) by excitation under nitrogen atmosphere with excitation light having a wavelength of 340 nm.

### Synthesis Example 1: Preparation of Light-Emitting Compound

2.128 grams (g) (10 millimole (mmol)) of CsBr as a first precursor was dissolved in 10 milliliters (mL) of deionized water at room temperature to prepare a first precursor solution. 3.670 g (10 mmol) of PbBr₂ as a second precursor was dissolved in 10 mL of hexamethyl phosphoamide (HMPA) at a temperature of 80° C. to prepare a second precursor solution and then the solution is lowered to room temperature. The first precursor solution was added dropwise to the second precursor solution at room temperature with stirring. The resulting precipitate was separated from the mixture, and the precipitate was washed with 1×20 mL of ethanol and 1×20 mL of diethylether. The resulting solid was dried in vacuum at a temperature of 60° C. for 12 hours to obtain 4.81 g of a prepared powder (yield: 83%).

(1) 0.58 g of the powder of Syn. Ex. 1 was mixed with 1 mL of DMSO. Ethyl acetate is then added in a 1.5 greater amount than the amount of DMSO, followed by stirring at a temperature of 80° C. for 30 minutes. The mixture was cooled to room temperature, and a green precipitate formed. The mixture was centrifuged at a 5,000 rpm for 10 minutes and the precipitate separated to obtain Light-emitting Compound 1-1.

(2) 0.58 g of the powder of Syn. Ex. 1 was mixed with 1 g of MPSO, and the mixture stirred at a temperature of 80° C. for 30 minutes. DMSO at room temperature, which corresponds to a volume of 0.5 times to 0.8 times of MPSO, was then added to provide a green precipitate. The mixture was centrifuged at a 5,000 rpm for 10 minutes, and the precipitate separated to obtain Light-emitting Compound 1-2.

(3) 0.58 g of the powder of Syn. Ex. 1 was mixed with 0.5 g of DMSO. DPSO at room temperature, which corresponds to a volume of 0.5 times of DMSO, was then added to provide a green precipitate. The mixture was centrifuged at a 5,000 rpm for 10 minutes, and the precipitate separated to obtain Light-emitting Compound 1-3.

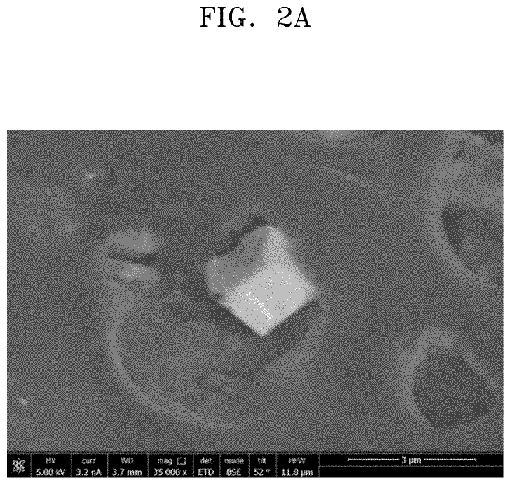

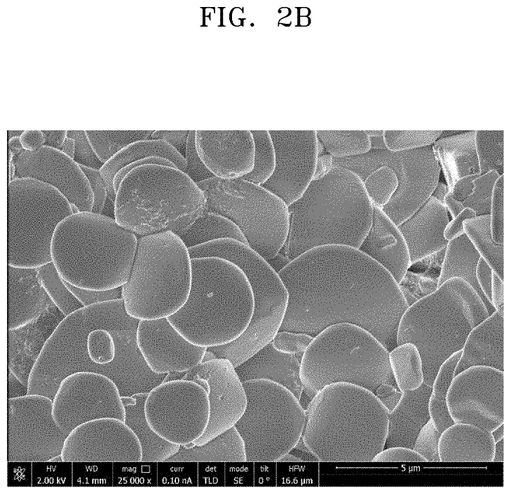

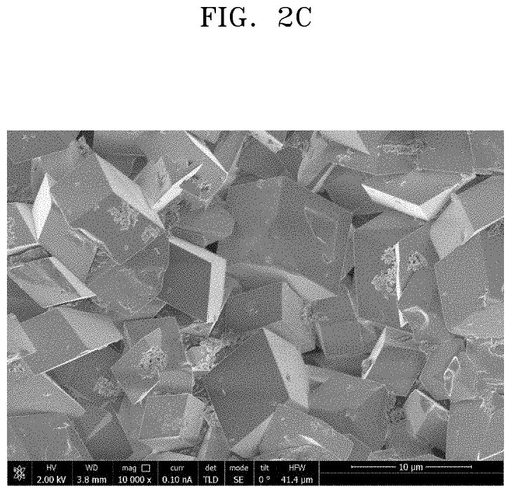

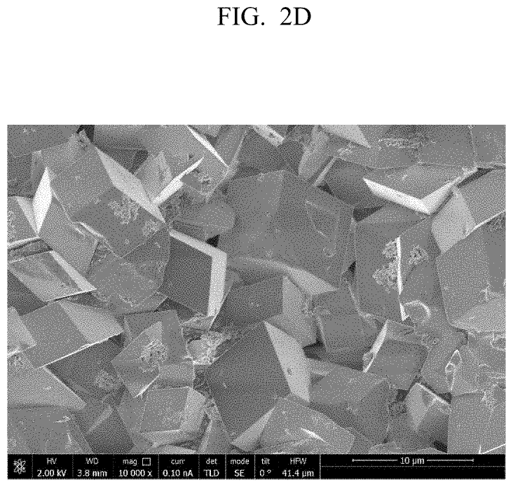

The SEM image of Light-emitting Compound 1-1 is shown in FIG. 2A. The SEM 18 image of Light-emitting Compound 1-2 is shown in FIG. 2B. The SEM image of Light-emitting Compound 1-3 is shown in FIG. 2C.

### Synthesis Example 2: Preparation of Light-Emitting Compound

2.128 g (10 mmol) of CsBr as a first precursor was dissolved in 10 mL of deionized water at room temperature to prepare a first precursor solution. 3.670 g (10 mmol) of PbBr₂ as a second precursor was dissolved in 10 mL of hexamethyl phosphoamide (HMPA) at a temperature of 80° C. to prepare a second precursor solution and the solution lowered to room temperature. The first precursor solution was added dropwise to the second precursor solution at room temperature with stirring. The resulting precipitate was separated from the mixture and washed with 1×20 mL of ethanol and 1×20 mL of diethylether. The resulting solid was dried in vacuum at a temperature of 60° C. for 12 hours to obtain 4.81 g of a prepared powder (yield: 83%).

(1) 0.58 g of the powder of Syn. Ex. 2 and 0.056 g (0.5 mmol) to 0.112 g (1 mmol) of MABr were mixed with 1 mL of DMSO. Ethyl acetate, which corresponds to a volume of 1.5 times of DMSO, was added with stirring at a temperature of 80° C. for 30 minutes. The mixture was cooled to room temperature, and a green precipitate formed. The mixture was centrifuged at a 5,000 rpm for 10 minutes, and the precipitate separated to obtain Light-emitting Compound 2-1. The PLQY of Light-emitting Compound 2-1 was about 80%.

(2) 0.58 g of the powder of Syn. Ex. 2 and 0.056 g (0.5 mmol) to 0.112 g (1 mmol) of MABr were mixed with 1 g of MPSO, followed by stirring at a temperature of 80° C. for 30 minutes. DMSO at room temperature, which corresponds to a volume of 0.5 times to 0.8 times of MPSO, was added with stirring to form a green precipitate. The mixture was 6 centrifuged at a 5,000 rpm for 10 minutes, and the precipitate separated to obtain Light-emitting Compound 2-2. The PLQY of Light-emitting Compound 2-2 was about 95%.

(3) 0.58 g of the powder of Syn. Ex. 2 and 0.056 g (0.5 mmol) to 0.112 g (1 mmol) of MABr were mixed with 0.5 g of DMSO. Then, DPSO at room temperature, which corresponds to a volume of 0.5 times of DMSO, was added thereto to form a green precipitate. The mixture was centrifuged at a 5,000 rpm for 10 minutes, and the precipitate separated to obtain Light-emitting Compound 2-3.

(4) 0.58 g of the powder of Syn. Ex. 2 and 0.056 g (0.5 mmol) to 0.112 g (1 mmol) of MABr were mixed with 1 g of MPSO, followed by stirring at a temperature of 80° C. for 30 minutes. Tetrahydro thiophene-1-oxide at room temperature, which corresponds to a volume of 0.5 times to 0.8 times of MPSO, was added thereto to form a green precipitate. The mixture was centrifuged at a 5,000 rpm for 10 minutes, and the precipitate separated to obtain Light-emitting Compound 2-4. The PLQY of Light-emitting Compound 2-4 was about 98%.

The SEM image of Light-emitting Compound 2-4 is shown in FIG. 2D.

### Example 1: Preparation of Light-Emitting Material

1 g of 3-aminopropyltriethoxy silane was added to 1 g of Light-emitting Compound 1-2, followed by stirring. The resulting mixture was drop-casted to obtain Samples 1, 2, and 3, which were heat-treated at a temperature of 120° C., 150° C., and 180° C., respectively, in air.

Comparative samples were also prepared: Comparative Sample 1, which was not heat-treated; Comparative Sample 2, in which methyl trimethoxy silane was added to Light-emitting Compound 1-2 instead of 3-aminopropyltriethoxy silane and heat-treated at a temperature of 150° C.; and Comparative Sample 3, in which phenethyl amine was added instead of 3-aminopropyltriethoxy silane and heat-treated at a temperature of 150° C.

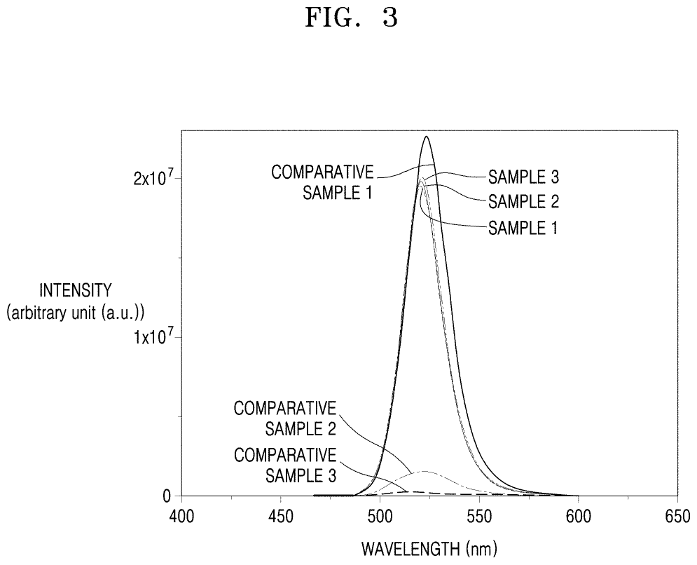

In addition, PL spectra and PLQY of Samples 1, 2, and 3 and Comparative Samples 1, 2 and 3 were measured. The results are shown in FIG. 3 and Table 1. The PLQY of Comparative Samples 2 and 3 were not measurable as the PLQY of Comparative Samples 2 and 3 may each be 0.1% or lower.

TABLE 1

| | Heat treatment | |
|---|---|---|
| Compound No. | temperature (° C.) | PLQY (%) |
| Sample 1 | 120 | 94.9 |
| Sample 2 | 150 | 94.9 |
| Sample 3 | 180 | 95 |
| Comp. Sample 1 | Not heat-treated | 99.8 |

As shown in FIG. 3, Samples 1 to 3 were each found to include an aminosiloxane structural unit. While not wishing to be bound by theory, the aminosiloxane, e.g., the 3-aminopropyltriethoxy silane, may be hydrolyzed in air by water to form siloxane.

In addition, as shown in FIG. 3 and Table 1, Samples 1, 2, and 3 were each heat-treated. However, even after the heat treatment, the Samples were each found to have relatively high PL intensity and PLQY.

As apparent from the foregoing description, the luminescence efficiency of the light-emitting material may not be significantly reduced as a result of a heat treatment. Thus, a light-emitting device including the light-emitting material may have improved lifespan and/or efficiency.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A light-emitting material comprising aminosiloxane and a light-emitting compound represented by Formula 1:
A¹B¹X¹₃ Formula 1
wherein, in Formula 1,
A¹ is an alkali metal,
B¹ is Pb, Sn, or any combination thereof, and
X¹ is a halogen.

2. The light-emitting material of claim 1, wherein A¹ is Cs, B¹ is Pb, and X¹ is Cl, Br, I, or any combination thereof.

3. The light-emitting material of claim 1, wherein the light-emitting compound represented by Formula 1 comprises CsPbBr₃, CsPbBrₓCl₍₃₋ₓ₎, wherein x is a real number greater than 0 and less than 3, CsPbCl₃, or any combination thereof.

4. The light-emitting material of claim 1, wherein the aminosiloxane comprises a structural unit represented by Formula 2: 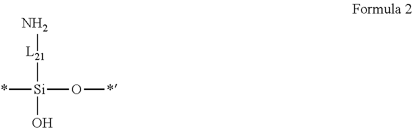
wherein, in Formula 2,
L₂₁ is a substituted or unsubstituted C₁-C₁₀ alkylene group, and
* and *′ each indicate a binding site to an adjacent atom.

5. The light-emitting material of claim 1, wherein the light-emitting material further comprises a dopant represented by Formula 3:
C¹X¹ Formula 3
wherein, in Formula 3,
C¹ is H, methylammonium (MA), formamidinium (FA), an alkali metal, or any combination thereof, and
X¹ is a halogen.

6. The light-emitting material of claim 1, wherein the light-emitting material further comprises amino alkoxysilane.

7. A light-emitting device comprising:
a first electrode and a second electrode each having a surface opposite the other; and
an emission layer positioned between the first electrode and the second electrode,
wherein the emission layer comprises the light-emitting material of claim 1.

8. The light-emitting device of claim 7, further comprising a hole transport region between the first electrode and the emission layer, an electron transport region between the emission layer and the second electrode, or a hole transport region between the first electrode and the emission layer and an electron transport region between the emission layer and the second electrode.

9. The light-emitting device of claim 7, further comprising a charge control layer between the first electrode and the emission layer, a charge control layer between the emission layer and the second electrode, or a charge control layer between the first electrode and the emission layer and a charge control layer between the emission layer and the second electrode.

10. A method of preparing a light-emitting material, the method comprising:
applying a mixture including a light-emitting compound represented by Formula 1, amino alkoxysilane, and a solvent onto a substrate; and
heat-treating the substrate:
A¹B¹X¹₃ Formula 1
wherein, in Formula 1,
A¹ is an alkali metal,
B¹ is Pb, Sn, or any combination thereof, and
X¹ is a halogen.

11. The method of claim 10, wherein the heat-treating is performed at a temperature of 100° C. or higher.

12. A method of preparing a light-emitting compound, the method comprising:
mixing a first precursor solution, which comprises a first precursor and a first solvent, with a second precursor solution, which comprises a second precursor and a second solvent, to form a precipitate;
separating the precipitate and dispersing the separated precipitate in a third solvent; and
adding a first compound to the dispersed precipitate to obtain the light-emitting compound,
wherein a solubility of the first precursor in the first solvent is greater than a solubility of the first precursor in the second solvent,
a solubility of the second precursor in the second solvent is greater than a solubility of the second precursor in the first solvent, and
the third solvent is different from the first compound.

13. The method of claim 12, wherein the third solvent comprises a sulfoxide group.

14. The method of claim 12, wherein the third solvent is dimethyl sulfoxide or methyl phenyl sulfoxide.

15. The method of claim 12, wherein the first compound is ethyl acetate, DMSO, tetramethylene sulfoxide, or diphenyl sulfoxide.

16. The method of claim 12, wherein
the third solvent is dimethyl sulfoxide, and the first compound is ethyl acetate;
the third solvent is methyl phenyl sulfoxide, and the first compound is dimethyl sulfoxide;
the third solvent is methyl phenyl sulfoxide, and the first compound is tetramethylene sulfoxide; or
the third solvent is dimethyl sulfoxide, and the first compound is diphenyl sulfoxide.

17. The method of claim 12, wherein the light-emitting compound comprises a light-emitting compound represented by Formulae 3, 4, or 5:
A³B³X³₃ Formula 3
A⁴B⁴₂X⁴₅ Formula 4
A⁵₄B⁵X⁵₆ Formula 5
wherein, in Formulae 3, 4, or 5,
A³, A⁴, and A⁵ are each independently an alkali metal,
B³, B⁴, and B⁵ are each independently Pb, Sn, or any combination thereof, and
X³, X⁴, and X⁵ are each independently a halogen.

18. The method of claim 17, wherein
i. the light-emitting compound comprises the light-emitting compound represented by Formula 3, and does not comprise the light-emitting compound represented by Formula 4 and the light-emitting compound represented by Formula 5,
ii. the light-emitting compound comprises the light-emitting compound represented by Formula 3 and the light-emitting compound represented by Formula 4, and does not comprise the light-emitting compound represented by Formula 5,
iii. the light-emitting compound comprises the light-emitting compound represented by Formula 3 and the light-emitting compound represented by Formula 5, and does not comprise the light-emitting compound represented by Formula 4, or
iv. the light-emitting compound comprises the light-emitting compound represented by Formula 5, and does not comprise the light-emitting compound represented by Formula 3 and the light-emitting compound represented by Formula 4.

19. The method of claim 17, wherein
the light-emitting compound comprises the light-emitting compound represented by Formula 3, and does not comprise the light-emitting compound comprises the light-emitting compound represented by Formula 4 and the light-emitting compound represented by Formula 5.

20. The method of claim 12, wherein
the first solvent comprises water, and
the second solvent comprises hexamethyl phosphoamide.
